(19) United States
(12) Patent Application Publication
(10) Pub. No.: US 2012/0280177 A1
(43) Pub. Date: Nov. 8, 2012

(54) ORGANIC FIBER FOR SOLAR PANEL AND PHOTOLUMINESCENT ELEMENT AND MATERIAL FOR PREPARING THE SAME

(76) Inventors: Jean-Hong CHEN, Tainan City (TW); Chien-Yi LI, Tainan City (TW); Jia-Cheng LI, Yuntin County (TW)

(21) Appl. No.: 13/100,659

(22) Filed: May 4, 2011

(51) Int. Cl. C09K 11/06; D02G 3/00

(52) U.S. Cl. 252/301.35; 428/373

(57) ABSTRACT

An organic fiber for a solar panel and a photoluminescent element and a material for preparing the same are provided. An organic conjugated polymer is dissolved in a solvent and is used to prepare an organic conjugated polymer fiber directly in an electrospinning process. The organic conjugated polymer fiber is applied in an organic photoluminescent base material with a high luminous efficiency or an organic solar panel with a high absorption efficiency. The organic conjugated polymer fiber is prepared directly by using the electrospinning process, and a diameter of the organic conjugated polymer fiber is between about 10 nm and 100 μm. The organic conjugated polymer fiber prepared by the present invention has the characteristics of polymer orientation and high specific surface area, thereby improving the light absorption efficiency, and further has the properties of high crystallinity and continuity, thereby improving the light transmission efficiency and photovoltaic conversion efficiency of the organic solar panel.

### BACKGROUND

1. Field of Invention

The present invention relates to an organic fiber for a solar panel and a photoluminescent element and a material for preparing the same. More particularly, the present invention relates to an organic conjugated polymer fiber fabricated directly by using an electrospinning process without adding other ingredients, and a material for preparing the same.

2. Description of Related Art

Taiwan Patent Publication No. 200833888 entitled “Light Emitting Fiber and Material Thereof” describes that a light emitting fiber material is usually a brittle material, so in practice, there is always a problem of fiber fracture in an electrospinning process which badly needs to be solved. Therefore, the Patent Publication No. 200833888 provides a light emitting fiber material, which can be suitably prepared by using the electrospinning process. As for the light emitting fiber material, a doped conjugated light emitting polymer is mixed with a non-conjugated polymer to prepare a core/shell-containing double-layer structure fiber. Then, the shell non-conjugated polymer is dissolved in a solvent to form a light emitting nanofiber.

Moreover, Taiwan Patent Publication No. 200833889 entitled “Light Emitting Fiber Material” describes that a light emitting fiber material is usually a brittle material, so in practice, there is always a problem of fiber fracture in the electrospinning process which badly needs to be solved. Therefore, the Patent Publication No. 200833889 provides a light emitting fiber material, which is prepared by using an electrospinning process. As for the light emitting fiber material, a conjugated light emitting polymer and a polymer material containing hydrophilic groups are used to prepare a core/shell-containing double-layer structure fiber. Then, the polymer material containing hydrophilic groups is dissolved in a solvent to form a light emitting nanofiber.

However, the above patents have the following major deficiencies. The above processes are complicated (the conjugated light emitting polymer needs to be mixed with other polymer materials and afterwards the non-conjugated polymer materials must be dissolved in the solvent), the structure of the prepared conjugated polymer fiber is difficult to control, and the processes have a high cost.

### SUMMARY

Accordingly, the present invention is directed to providing a material for preparing an organic conjugated polymer fiber by using an electrospinning process, thereby achieving a high light absorption efficiency and a high light conversion efficiency.

Furthermore, the present invention relates to an organic solar panel fiber and more particularly to a nanometer-scale organic polymer fiber, and specifically relates to a conjugated polymer fiber for organic solar panels prepared by using an electrospinning process and a material for preparing the same.

An organic polymer fiber for organic solar panels is a photoelectric or light conversion material that attracts much attention and is widely applied in a variety of industries, such as personal organic solar panels, industrial organic solar panels, home organic solar panels, outdoor organic solar panels and organic solar panels for 3C products.

In addition, the present invention relates to an organic photoluminescent fiber and more particularly to a nanometer-scale fiber, and specifically relates to a conjugated polymer photoluminescent fiber prepared by using an electrospinning process and a material thereof.

A conjugated polymer photoluminescent fiber is one of the materials for a photoelectric display or a photoluminescent element, which attracts much attention and can be applied in a variety of industries, such as personal display panels, industrial light emitting elements, home light emitting elements, outdoor (indoor) light emitting elements and organic light emitting elements for 3C products. The conjugated polymer fiber prepared by the present invention is fabricated directly by using an electrospinning process without adding other materials.

The material for preparing the organic conjugated polymer fiber of the present invention includes a conjugated polymer and a solvent. The solvent is a single solvent or a cosolvent. The single solvent includes one selected from the group consisting of chloromethane, dichloromethane, chloroform, toluene and xylene, and the cosolvent is formed by at least two solvents selected from the group consisting of chloromethane, dichloromethane, chloroform, toluene and xylene.

The present invention provides a material for preparing an organic conjugated polymer fiber directly by using an electrospinning process, in which additional materials and post-processes are not required, and the electrospinning process is directly adopted for preparing the organic conjugated polymer fiber, which is economic and beneficial.

The organic conjugated polymer photoluminescent fiber of the present invention is a continuous and non-fracture fiber which has stronger light absorption and photoluminescence capabilities than ordinary films, thus facilitating the improvement of the light energy conversion efficiency of the organic photoluminescent element.

The conjugated polymer fiber provided by the present invention is a continuous and non-fracture fiber which has a stronger light absorption capability than ordinary films and has a smaller photoluminescence behavior, thus facilitating the improvement of the light energy conversion efficiency of the organic solar panels.

The present invention adopts a conjugated polymer and a solvent which are directly formulated in an electrospinning process to form an organic solar panel fiber, thereby preparing a continuous fiber with a smooth surface or an uneven surface, and a diameter of the prepared organic fiber can be controlled to change it from a micron scale to a nanometer scale. Thus, a light scattering behavior among organic fibers is used to increase a wavelength range of an absorption spectrum of the organic fiber, and an internal molecular chain of the organic fiber has an obvious orientation, thereby significantly improving the transmission rate of electron-hole particles inside the organic fiber material. Therefore, the present invention has a higher light absorption efficiency and a higher light conversion efficiency.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The invention can be more fully understood by reading the following detailed description of the embodiments, with reference made to the accompanying drawings as follows:

FIG. 1 is a schematic view of an organic solar panel P3HT nanofiber material according to an embodiment of the present invention, with 400× magnification;

FIG. 2 is a schematic view of an organic photoluminescent PFO nanofiber material according to an embodiment of the present invention, with 400× magnification;

FIGS. 3 (a), (b), (c) are optical microscopy pictures of a prepared organic solar panel P3HT nanofiber, with 400× magnification;

FIGS. 4 (a), (b), (c) are optical microscopy pictures of a prepared organic photoluminescent PFO nanofiber, with 400× magnification;

FIG. 5 is a UV light absorption and PL photoluminescence spectrogram of the prepared organic solar panel P3HT nanofiber, P3HT solution and P3HT gel dripping film;

FIG. 6 is a UV light absorption and PL photoluminescence spectrogram of the prepared organic photoluminescent PFO nanofiber, PFO solution and PFO gel dripping film;

FIGS. 7 (a), (b) are electronic microscopy pictures of the prepared organic solar panel P3HT nanofiber: (a) with 500× magnification; (b) with 5,000× magnification;

FIGS. 8 (a), (b) are electronic microscopy pictures of the prepared organic photoluminescent PFO nanofiber: (a) with 500× magnification; (b) with 5,000× magnification;

FIGS. 9 (a), (b) are electronic microscopy pictures of the prepared organic solar panel P3HT nanofiber: (a) with 1,000× magnification; (b) with 10,000× magnification; and

FIG. 10 is an electronic microscopy picture of the prepared organic solar panel P3HT nanofiber having a diameter of 200 nm, with 20,000× magnification.

### DETAILED DESCRIPTION

To make the above features and advantages of the present invention more apparent, the embodiments thereof will be described in detail below with reference to the accompanying drawings.

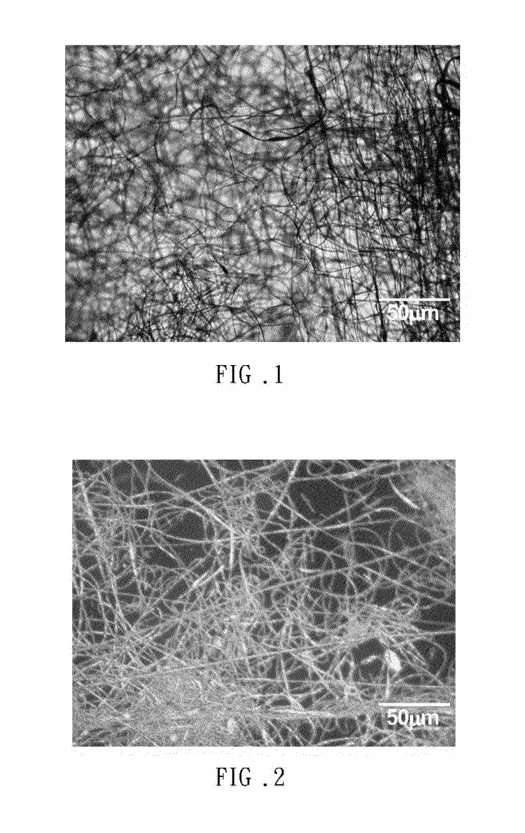

FIG. 1 illustrates that a prepared nano-organic polymer fiber for organic solar panels is a continuous nanofiber, and the nano-organic fiber for organic solar panels of this embodiment is formed directly by electrospinning a conjugated polymer.

FIG. 2 illustrates that the prepared nano-organic fiber for organic solar panels is a continuous nanofiber, and the photoluminescent nano-organic fiber of this embodiment is also formed directly by electrospinning a conjugated polymer.

In the above embodiment, for example, the conjugated polymer is one selected from the group consisting of poly-3-alkylthiophene and its derivatives, PFO and its derivatives, PPV and its derivatives, and poly-p-phenylene and its derivatives.

In the above embodiment, the conjugated polymer includes a conjugated polymer mixture selected from the group consisting of a conjugated polymer mixture of polythiophene and its derivatives and polyfluorene and its derivatives, a conjugated polymer mixture of polythiophene and its derivatives and poly(phenylene vinylene) and its derivatives, a conjugated polymer mixture of polythiophene and its derivatives and poly(phenylene vinylene) and its derivatives, a conjugated polymer mixture of polyfluorene and poly(phenylene vinylene) and its derivatives, and a conjugated polymer mixture of polyfluorene and poly-p-phenylene and its derivatives. A weight ratio between the mixed conjugated polymers is between 1:99 and 99:1.

In the above embodiment, the conjugated polymer includes a conjugated copolymer material selected from the group consisting of: a conjugated copolymer material of PFO and its derivatives and poly (fluorine-co-thiophene), a conjugated copolymer material of poly (fluorine-co-phenylene vinylene) and a conjugated copolymer material of poly (thiophene-co-phenylene vinylene) and its derivatives.

Moreover, the solvent for the nano-organic polymer fiber material for organic solar panels of this embodiment includes a single solvent or a cosolvent. The single solvent includes chloromethane, dichloromethane, toluene, chloroform or xylene, and the cosolvent is formed by at least two solvents selected from the group consisting of chloromethane, dichloromethane, toluene, chloroform and xylene. If the cosolvent is formed by toluene and xylene, a volume ratio between toluene and xylene is between 99:1 and 1:99.

First, the conjugated polymer material is dissolved in an appropriate solvent (e.g. toluene) and then injected into a syringe. Thereafter, the conjugated polymer material is ejected from a nozzle end by an electrostatic force under a high voltage, so as to form a liquid column. The liquid column with electrons is then stretched and whipped by the electrostatic force, and consequently the fiber diameter is gradually reduced. Accordingly, the solvent in the conjugated polymer solution is continuously volatized, so the diameter of the conjugated polymer fiber is greatly reduced from hundreds of microns to tens of nanometers. Then, the organic fiber material for organic solar panels which has a diameter of about 10 nm to 100 μm is collected by a grounded collection plate.

Hereinafter, an experimental example will be used to describe the optical characteristics of the organic solar panel nanofiber of the present invention.

### Example

A conjugated polymer material of poly (3-hexylthiophene-2,5-diyl) (P3HT) or a conjugated polymer material of poly (9,9-dioctylfluorene-2,7-diyl) (PFO) is adopted, chloroform is used as a solvent, and a concentration of the conjugated polymer material is 4.0-40.0 wt %. The experiment is under the condition that a distance from the nozzle end to the collection plate is about 10-50 cm, the high voltage is 5-35 KeV, and a flow rate of the conjugated polymer is about 0.5-10 ml/h. The P3HT organic polymer fiber for organic solar panels is prepared by using an electrospinning process, or the photoluminescent PFO organic polymer fiber is prepared by using the electrospinning process.

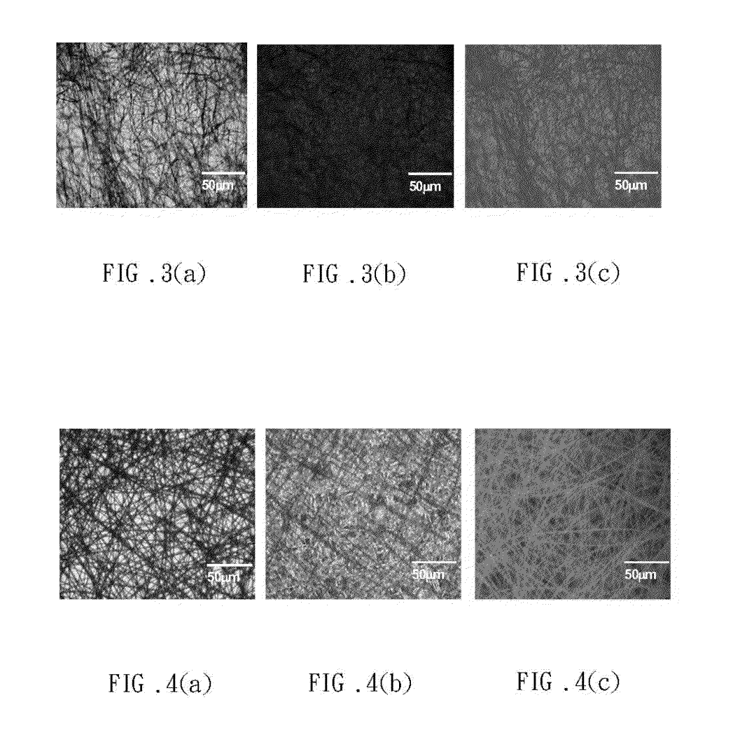

In FIG. 3: (a) is a picture of the P3HT nanofiber observed under OM; (b) is a picture of the P3HT nanofiber observed under POM; and (c) illustrates a photoluminescence behavior of the P3HT nanofiber irradiated by a 320 nm excitation light source. It can be seen from FIG. 3(b) that the P3HT nanofiber under POM is a nanofiber material having a crystalline optical characteristic. FIG. 3(c) shows that the P3HT nanofiber irradiated by a UV light does not cause a photoluminescence behavior, which proves that its light absorption efficiency is significantly improved.

In FIG. 4: (a) is a picture of the PFO nanofiber observed under OM; (b) is a picture of the PFO nanofiber observed under POM; and (c) illustrates a photoluminescence behavior of the PFO nanofiber irradiated by a 320 nm excitation light source. It can be seen from FIG. 4(b) that the PFO nanofiber under POM is a nanofiber material having an optical characteristic of highly oriented crystalline. FIG. 4(c) shows that the PFO nanofiber irradiated by the UV light presents a wonderful blue-light luminescence behavior, which proves that its luminescence behavior has a blue shift phenomenon.

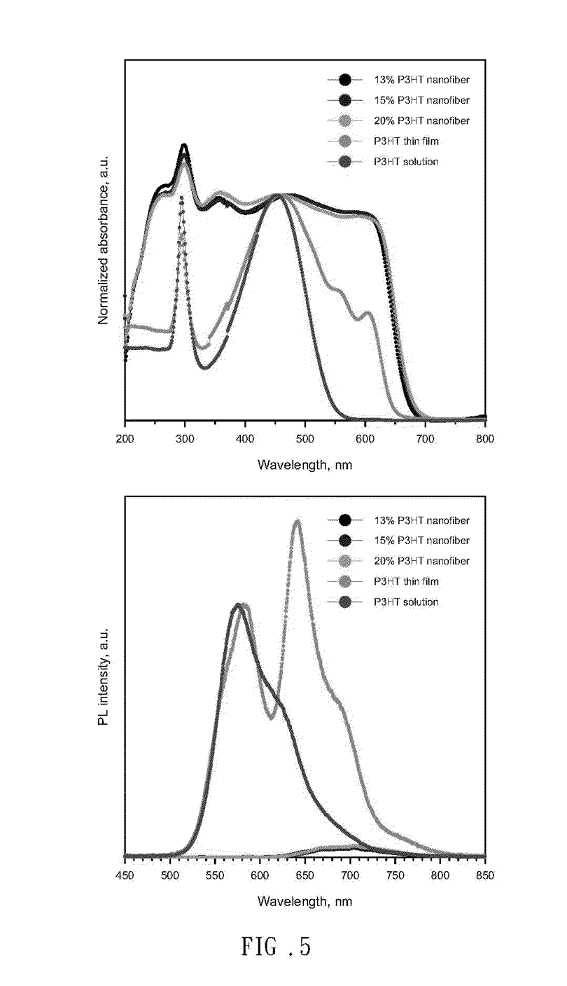

In FIG. 5: (a) is a UV light absorption spectrogram and (b) is a PL photoluminescent spectrogram. FIG. 5(a) illustrates that the light absorption efficiency of the P3HT polymer nanofiber is obviously higher than that of the P3HT solution and P3HT gel film. FIG. 5(b) illustrates that the luminescence behavior of the P3HT nanofiber in the PL photoluminescent spectrogram is obviously lower than that of the P3HT solution and P3HT gel film, which indicates that the absorbed light energy will not be excited and the light conversion efficiency is significantly improved.

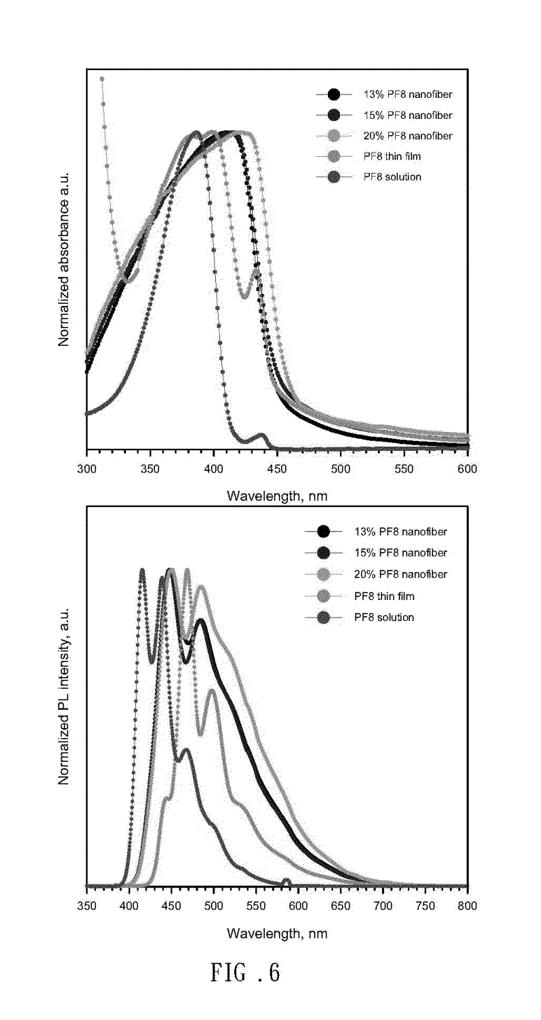

In FIG. 6: (a) is a UV light absorption spectrogram and (b) is a PL photoluminescent spectrogram. FIG. 6(a) illustrates that the width of absorption of the PFO polymer nanofiber is obviously larger than that of the PFO solution and PFO gel film, which indicates that the PFO polymer nanofiber has a higher light absorption efficiency. FIG. 6(b) illustrates that the luminescence behavior of the PFO nanofiber in the PL photoluminescent spectrogram is obviously higher than that of the PFO solution and PFO and has a blue shift, which indicates that the PFO polymer nanofiber has a higher photoluminescence efficiency and the light conversion efficiency is significantly improved.

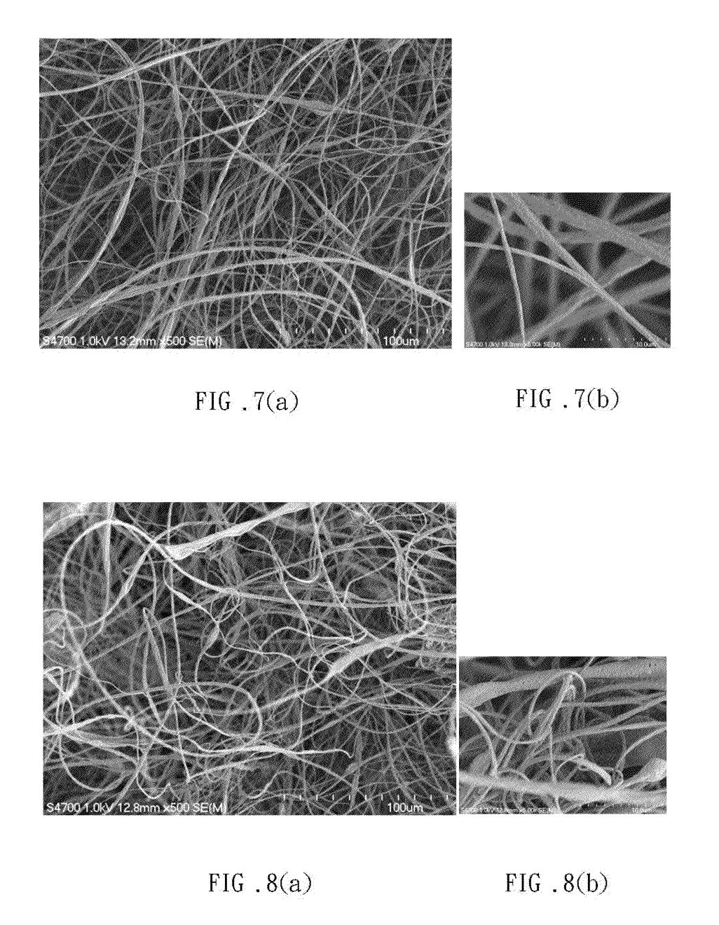

FIGS. 7 (a), (b) are electronic microscopy pictures of the prepared organic solar panel P3HT polymer nanofiber.

FIGS. 8 (a), (b) are electronic microscopy pictures of the prepared organic photoluminescent PFO polymer nanofiber.

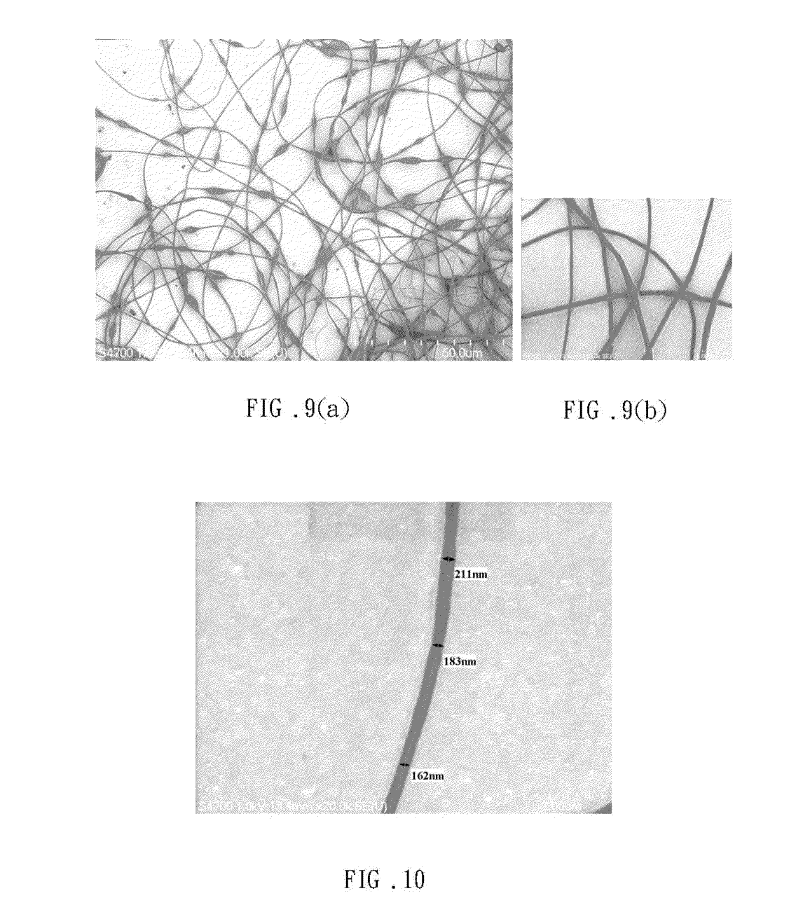

FIGS. 9 (a), (b) are electronic microscopy pictures of the prepared organic solar panel P3HT polymer nanofiber.

FIG. 10 is an electronic microscopy picture of the prepared organic solar panel P3HT polymer nanofiber having a diameter of about 200 nm.

In summary, the present invention has the following advantages. The organic polymer fiber material for a variety of organic solar panels and organic photoluminescence can be directly prepared by using an electrospinning process, and the diameter of the prepared organic fiber material is 10 nm to 100 μm.

The organic photoluminescent fiber material prepared by the present invention has a larger light absorption range than an ordinary spin-coating film, and the photoluminescence intensity of the prepared organic photoluminescent nanofiber is higher than that of the spin-coating film. Therefore, the light absorption efficiency and the photoluminescence efficiency are significantly increased. A conjugated polymer photoluminescent nano-organic fiber is one of the materials for a photoelectric display or photoluminescent element, which attracts much attention and can be applied in a variety of industries, such as personal display panels, industrial light emitting elements, home light emitting elements, outdoor (indoor) light emitting elements and organic light emitting elements for 3C products. The conjugated polymer prepared by the present invention is fabricated directly by using the electrospinning process without adding other materials.

In addition, the organic fiber material for organic solar panels prepared by the present invention has a larger light absorption range than the spin-coating film, and the prepared nano-organic fiber material for organic solar panels has a smaller photoluminescence behavior, so the light absorption efficiency and the light conversion efficiency can be significantly increased. The conjugated polymer of the present invention is fabricated into a nano-organic fiber material organic solar panels, which can be widely applied in a variety of industries, such as personal organic solar panels, industrial organic solar panels, home organic solar panels, outdoor organic solar panels and organic solar panels for 3C products.

What is claimed is:

1. An organic fiber for a solar panel and a photoluminescent element, fabricated directly by using an electrospinning process, comprising a conjugated polymer.

2. The organic fiber for a solar panel and a photoluminescent element of claim 1, wherein the conjugated polymer is one selected from the group consisting of poly-3-alkylthiophene and its derivatives, PFO and its derivatives, PPV and its derivatives and poly-p-phenylene and its derivatives.

3. The organic fiber for a solar panel and a photoluminescent element of claim 1, wherein the conjugated polymer comprises a conjugated polymer mixture selected from the group consisting of a conjugated polymer mixture of polythiophene and its derivatives and polyfluorene and its derivatives, a conjugated polymer mixture of polythiophene and its derivatives and poly(phenylene vinylene) and its derivatives, a conjugated polymer mixture of polythiophene and its derivatives and poly-p-phenylene and its derivatives, a conjugated polymer mixture of polyfluorene and poly(phenylene vinylene) and its derivatives and a conjugated polymer mixture of polyfluorene and poly-p-phenylene and its derivatives.

4. The organic fiber for a solar panel and a photoluminescent element of claim 3, wherein in the conjugated polymer mixture, a weight ratio between the mixed conjugated polymers is between 1:99 and 99:1.

5. The organic fiber for a solar panel and a photoluminescent element of claim 1, wherein the conjugated polymer comprises a conjugated copolymer material selected from the group consisting of a conjugated copolymer material of PFO and its derivatives and poly (fluorine-co-thiophene), a conjugated copolymer material of poly (fluorine-co-phenylene vinylene), and a conjugated copolymer material of poly (thiophene-co-phenylene vinylene) and its derivatives.

6. The organic fiber for a solar panel and a photoluminescent element of claim 1, wherein a diameter of the organic fiber is between 10 nm and 100 μm.

7. A material for preparing the organic fiber of claim 1, comprising a conjugated polymer and a solvent, wherein the solvent is a single solvent or a cosolvent.

8. The material of claim 7, wherein the single solvent comprises one selected from the group consisting of chloromethane, dichloromethane, toluene, chloroform and xylene.

9. The material of claim 7, wherein the cosolvent is formed by at least two solvents selected from the group consisting of chloromethane, dichloromethane, toluene, chloroform and xylene.
